(19) United States
(12) Patent Application Publication
(10) Pub. No.: US 2008/0257405 A1
(43) Pub. Date: Oct. 23, 2008

(54) Multijunction solar cell with strained-balanced quantum well middle cell

(75) Inventor: Paul Sharps, Albuquerque, NM (US)

Correspondence Address: EMCORE CORPORATION, 1600 EUBANK BLVD, S.E., ALBUQUERQUE, NM, 87123, US

(73) Assignee: Emcore Corp.

(21) Appl. No.: 11/788,315

(22) Filed: Apr. 18, 2007

(51) Int. Cl. H01L 31/00

(52) U.S. Cl. 136/256

(57) ABSTRACT

A multijunction photovoltaic cell including a top subcell; a second subcell disposed immediately adjacent to the top subcell and producing a first photo-generated current; and including a sequence of first and second different semiconductor layers with different lattice constant; and a lower subcell disposed immediately adjacent to the second subcell and producing a second photo-generated current substantially equal in amount to the first photo-generated current density.

### REFERENCE TO RELATED APPLICATIONS

This application is related to U.S. patent application Ser. No. 11/445,793 filed Jun. 2, 2006, assigned to the common assignee.

### BACKGROUND OF THE INVENTION

1. Field of the Invention

The present disclosure relates to solar cells and the fabrication of solar cells, and more particularly the design and specification of the middle cell in multifunction solar cells based on III-V semiconductor compounds.

2. Description of the Related Art

Photovoltaic cells, also called solar cells, are an important renewable source of electrical power that have become increasingly commercially important in the past several years. Solar cells currently are being used in a number of terrestrial and space applications, including satellites and other spacecraft. The energy conversion efficiency from solar energy or photons to electrical energy is a critical issue in the design and specification of solar cells. For example, in satellite and/or other space related applications, the size, mass, and cost of a satellite power system are directly related to the power and energy conversion efficiency of the solar cells used. Putting it another way, the size of the payload and the availability of on-board services are proportional to the amount of solar power that can be provided from the on-board solar cells. Thus, as the payloads become more sophisticated, solar cells, which act as the power generation devices for the on-board systems, become increasingly more important.

The efficiency of energy conversion, which converts solar energy (or photons) to electrical energy, depends on various factors such as the design of solar cell structures, the choice of semiconductor materials, and the thickness of each cell. In short, the energy conversion efficiency for each solar cell is dependent on the optimum utilization of the available. sunlight across the solar spectrum. As such, the characteristic of sunlight absorption in semiconductor material, also known as photovoltaic properties, is critical to determine the most efficient semiconductor to achieve the optimum energy conversion.

Commercially available silicon solar cells for terrestrial solar power applications have efficiencies ranging from 8% to 15%. Compound semiconductor solar cells, based on III-V compounds, such as those used in space applications, have 28% efficiency in normal operating conditions and over 38% efficiency under concentration. The highest conversion efficiencies have been achieved with multijunction solar cells.

Multijunction solar cells are formed by a vertical or stacked sequence of solar subcells, each subcell formed with appropriate semiconductor layers and including a p-n photoactive junction. Each subcell is designed to convert photons over different spectral or wavelength bands to electrical current. After the sunlight impinges on the front of the solar cell, and photons pass through the subcells, the photons in a wavelength band that are not absorbed and converted to electrical energy in the region of one subcell propagate to the next subcell, where such photons are intended to be captured and converted to electrical energy, assuming the downstream subcell is designed for the photon's particular wavelength or energy band.

The energy conversion efficiency of multijunction solar cells is affected by such factors as the number of subcells, the thickness of each subcell, and the band structure, electron energy levels, conduction, and absorption of each subcell. Factors such as the short circuit current density (J_{sc}), the open circuit voltage (V_{oc}), and the fill factor are also important.

One of the important mechanical or structural considerations in the choice of semiconductor layers for a solar cell is the desirability of the adjacent layers of semiconductor materials in the solar cell, i.e. each layer of crystalline semiconductor material that is deposited and grown to form a solar subcell, have similar crystal lattice constants or parameters.

Many III-V devices, including solar cells, are fabricated by thin epitaxial growth of III-V compound semi conductors upon a relatively thick substrate. The substrate, typically of Ge, GaAs, InP, or other bulk material, acts as a template for the formation of the deposited epitaxial layers. The atomic spacing or lattice constant in the epitaxial layers will generally conform to that of the substrate, so the choice of epitaxial materials will be limited to those having a lattice constant similar to that of the substrate material. FIG. 1 shows the relationship between the band gap of various III-V binary materials and common substrate materials. The characteristics of ternary III-V semiconductor alloys may also be inferred from the figure by referring to the solid lines between pairs of binary materials, e.g. the characteristics of an InGaAs alloy is represented by the line between GaAs and InAs, depending on the percentage of In found in the ternary alloy.

Assuming a Ge or GaAs substrate, the amount of lattice mismatch associated with an epitaxial layer with a predetermined atomic spacing is set forth in Table 1 below.

TABLE 1

| Atomic Spacing | Lattice |
|---|---|
| Epitaxial Layer | Mismatch |
| (Angstrom) | (percent) |
| 5.71 | 1% |
| 5.76 | 2% |
| 5.82 | 3% |
| 5.875 | 4% |
| 5.93 | 5% |

Mismatching of the lattice constant between adjacent semiconductor layers in the solar cells results in defects or dislocations in the crystal, which in turn causes degradation of photovoltaic efficiency by undesirable phenomena known as open-circuit voltage, short circuit current, and fill factor.

The energy conversion efficiency, i.e. the amount of electrical power produced by a given quantity or flux of incident photons on the solar cell, is measured by the resulting current and voltage referred to as the photocurrent and photovoltage. The aggregate photocurrent flow can be improved if each solar cell junction of the semiconductor device is current matched, in other words, the electrical characteristics of each solar subcell in the multijunction device is such that the electric current produced by each subcell is the same.

Current matching among the subcells is critical to the overall efficiency of the solar cell since in a multijunction solar cell device, the individual subcells in the device are electrically connected in series. In a series electrical circuit, the overall current flow though the circuit is limited to the smallest current capability of any one of the individual cells in the circuit. Current matching is essentially equalizing the current capability of each cell, by specifying and controlling (by control of the fabrication processes) both (i) the relative band gap energy absorption capabilities of the various semiconductor materials used to form the cell junctions, and (ii) the thicknesses of each semiconductor cell in the multijunction device.

In contrast to photocurrent, the photovoltages produced by each semiconductor cell are additive, and preferably each semiconductor cell within a multi-cell solar cell is selected to provide small increments of power absorption (e.g., a series of gradually reducing band gap energies) to improve the total power, and specifically the voltage, output of the solar cell.

The control of these parameters during fabrication is the appropriate selection, out of a large number of materials and material compounds, of the most suitable material structures. However, these prior art solar cell layers have often been lattice mismatched, which may lead to photovoltaic quality degradation and reduced efficiency, even for slight mismatching, such as less than one percent. Further, even when lattice-matching is achieved, these prior art solar cells often fail to obtain desired photovoltage outputs. This low efficiency is caused, at least in part, by the difficulty of lattice-matching each semiconductor cell to commonly used and preferred materials for the substrate, such as germanium (Ge) or. gallium-arsenide (GaAs) substrates.

As discussed above, it is preferable that each sequential junction absorb energy with a slightly smaller band gap to more efficiently convert the full spectrum of solar energy. In this regard, solar cells are stacked in descending order of band gap energy. However, the limited selection of known semiconductor materials, and corresponding band gaps, that have the same lattice constant as the above preferred substrate materials has continued to make it a challenge to design and fabricate multijunction solar cells with high conversion efficiency and reasonable manufacturing yields.

Physical or structural design of solar cells can also enhance the performance and conversion efficiency of solar cells, especially in multijunction structures that increase the coverage of the solar spectrum. Solar cells are normally fabricated by forming a homojunction between an n-type and a p-type layer. The thin, topmost layer of the junction on the sunward side of the device is referred to as the emitter. The relatively thick bottom layer is referred to as the base. However, one problem associated with the conventional multijunction solar cell structure is the relatively low performance relating to the homojunction middle solar cells in the multijunction solar cell structures. The performance of a homojunction solar cell is typically limited by the material quality of the emitter, which is low in homojunction devices. Low material quality usually includes such factors as poor surface passivation, lattice mismatch between layers and/or narrow band gaps of the selected material.

A multijunction solar cell structures that include multiple subcells vertically stacked one above the other absorb an increased range of the solar spectrum. Increasing device efficiency of multijunction solar cell structures through band-gap engineering and lattice matching alone, however, has proven increasingly challenging.

Conventional III-V solar cells typically use a variety of compound semiconductor materials such as indium gallium phosphide (InGaP), gallium arsenic (GaAs), germanium (Ge) and so forth, to increase coverage of the absorption spectrum from UV to 890 nm. For instance, use of a germanium (Ge) junction to the cell structure extends the absorption range (i.e. to 1800 nm). Thus, the appropriate selection of semiconductor compound materials can enhance the performance of the solar cell.

The present invention is directed to improvements in multijunction solar cell structures to improve photoconversion efficiency and current matching.

### SUMMARY OF THE INVENTION

### 1. Objects of the Invention

It is an object of the present invention to provide increased photoconversion efficiency in a multijunction solar cell.

It is another object of the present invention to provide increased current in a multijunction solar cell by utilizing lattice mismatched layers in the middle cell.

It is still another object of the present invention to provide a strain-balanced quantum well structure in the middle cell of a multifunction solar cell.

### 2. Features of the Invention

Briefly, and in general terms, the present invention provides a multijunction photovoltaic cell, including a top subcell; a second subcell disposed immediately adjacent to the top subcell, and producing a first photo-generated current; the subcell including a sequence of first and second different semiconductor layers with different lattice constant; and a lower subcell disposed immediately adjacent to the second subcell and producing a second photo-generated current substantially equal in amount to the first photo-generated current.

In another aspect, the present invention provides a multijunction solar cell including a semiconductor substrate; and a sequence of semiconductor layers disposed over the substrate and adapted to form a stack of subcells with the substrate, wherein a middle subcell of the stack comprises a sequence of alternating first and second semiconductor layers of different semiconductor material, and wherein the average lattice constant of the sequence of alternating first and second semiconductor layers is approximately equal to a lattice constant of the substrate.

Additional objects, advantages, and novel features of the present invention will become apparent to those skilled in the art form this disclosure, including the following detailed description as well as by practice of the invention. While the invention is described below with reference to preferred embodiments, it should be understood that the invention is not limited thereto. Those of ordinary skill in the art having access to the teachings herein will recognize additional applications, modifications and embodiments in other fields, which are within the scope of the invention as disclosed and claimed herein and with respect to which the invention could be of utility.

### BRIEF DESCRIPTION OF THE DRAWINGS

These and other features and advantages of this invention will be better understood and more fully appreciated by reference to the following detailed description when considered in conjunction with the accompanying drawings, wherein:

FIG. 1 is an example of a multijunction solar cell known in the prior art;

FIG. 2 is the photoconversion or quantum efficiency curve for the multijunction solar cell in FIG. 1;

FIG. 3 is an example of a multijunction solar cell according to the present invention; and

FIG. 4 is the photoconversion or quantum efficiency curve for the multijunction solar cell of FIG. 3.

Additional objects, advantages, and novel features of the present invention will become apparent to those skilled in the art from this disclosure, including the following detailed description as well as by practice of the invention. While the invention is described below with reference to preferred embodiments, it should be understood that the invention is not limited thereto. Those of ordinary skill in the art having access to the teachings herein will recognize additional applications, modifications and embodiments in other fields, which are within the scope of the invention as disclosed and claimed herein and with respect to which the invention could be of utility.

### DESCRIPTION OF THE PREFERRED EMBODIMENT

Details of the present invention will now be described including exemplary aspects and embodiments thereof. Referring to the drawings and the following description, like reference numbers are used to identify like or functionally similar elements, and are intended to illustrate major features of exemplary embodiments in a highly simplified diagrammatic manner. Moreover, the drawings are not intended to depict every feature of the actual embodiment nor the relative dimensions of the depicted elements, and are not drawn to scale.

The present invention relates generally to the identification and parametric environmental and operational data monitoring of pluggable optical communications modules such as transmitters, receivers, and transceivers used in fiber optic communications systems.

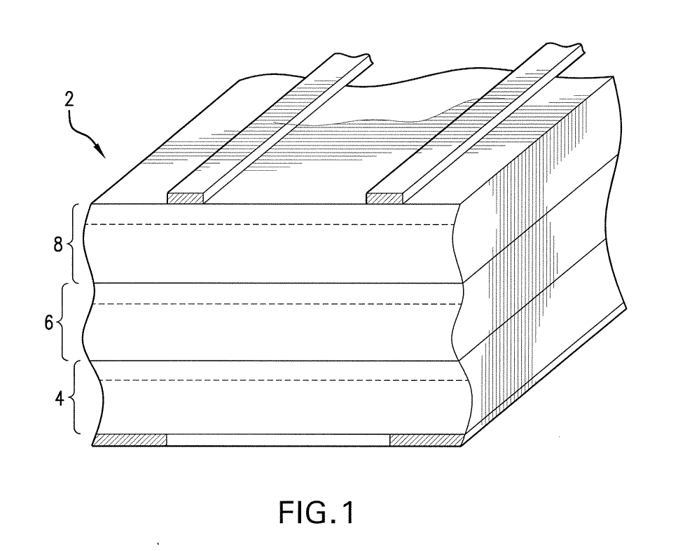

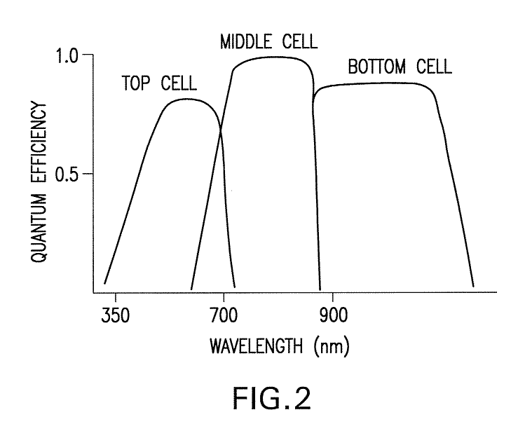

FIG. 1 illustrates an example of a typical multijunction solar cell 100 known in the prior art that includes a bottom subcell A, a middle subcell B and a top subcell C, formed as a stack of solar cells. The subcells A, B, and C include a sequence of semiconductor layers deposited one atop another. Each subcell within the multifunction solar cell 102 absorbs light in an active region over a respective range of wavelengths. The photoactive region or junction between a base layer and emitter layer of a solar subcell is indicated by a dashed line in each subcell. The quantum efficiency curve for the solar cell structure 2 is shown in FIG. 2. Under normal operation, the overall efficiency for the multijunction solar cell illustrated in FIG. 1 can approach approximately 29.5% under one sun, air mass zero (AM0) illumination conditions.

The active regions in each subcell do not generate equal amounts of current. Typically, the middle subcell B generates the least amount of photocurrent. In space (AM0) applications, radiation damage is a concern, and since the middle subcell is more susceptible to radiation damage than the top subcell, the top subcell C is designed for such applications to generate about 4-5% less current than the middle subcell B and approximately 30% less current than the bottom subcell A. Subsequently, over the course of fifteen to twenty years of use in high-radiation environments, radiation damage sustained by the middle subcell B can degrade the device performance such that the middle subcell B and top subcell C provide approximately equal current generation. Accordingly, for much of the device's lifetime, the top subcell C serves to limit the maximum amount of current generated by middle subcell B and bottom subcell A.

However, for terrestrial applications (at sea level, AM1), solar cells are not subject to radiation damage, and it may not be necessary to design the top cell with lower current.

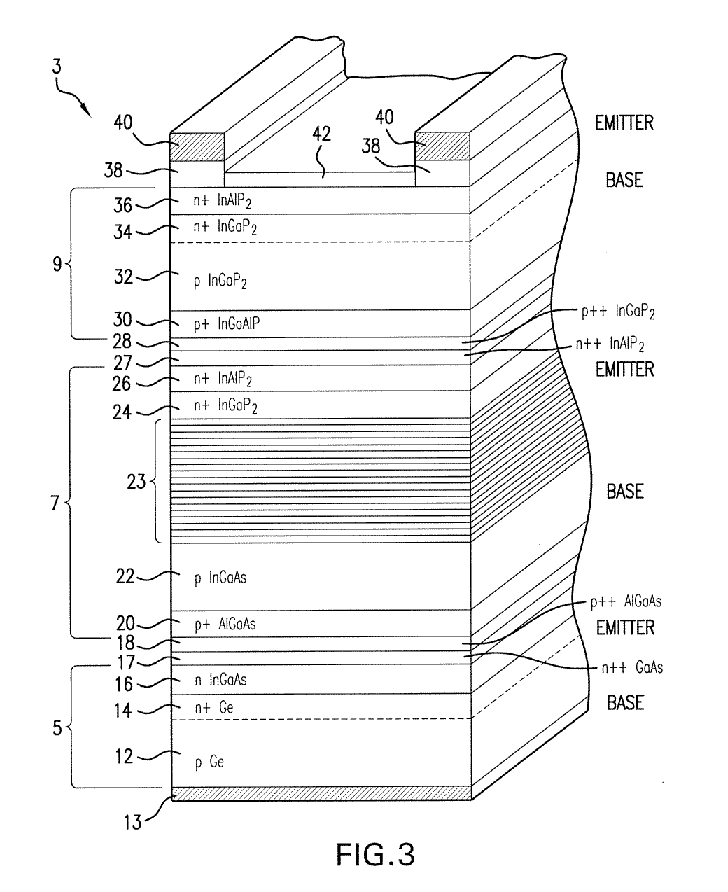

FIG. 3 illustrates a particular example of a multijunction solar cell device 303 in which the middle subcell 307 has been modified in order to provide an increase in the overall multijunction cell efficiency. As in FIG. 1, each dashed line indicates the active region junction between a base layer and emitter layer of a subcell.

As shown in the illustrated example of FIG. 3, the bottom subcell 305 includes a substrate 312 formed of p-type germanium (“Ge”) which also serves as a base layer. A contact pad 313 formed on the bottom of base layer 312 provides electrical contact to the multijunction solar cell 303. The bottom subcell 305 further includes, for example, a highly doped n-type Ge emitter layer 314, and an n-type indium gallium arsenide (“InGaAs”) nucleation layer 316. The nucleation layer is deposited over the base layer 312, and the emitter layer is formed in the substrate by diffusion of deposits into the Ge substrate, thereby forming the n-type Ge layer 314. Heavily doped p-type aluminum gallium arsenide (“AlGaAs”) and heavily doped n-type gallium arsenide (“GaAs”) tunneling junction layers 318, 317 may be deposited over the nucleation layer 316 to provide a low resistance pathway between the bottom and middle subcells.

In the illustrated example of FIG. 3, the middle subcell 307 includes a highly doped p-type aluminum gallium arsenide (“AlGaAs”) back surface field (“BSF”) layer 320, a p-type InGaAs base layer 322, a highly doped n-type indium gallium phosphide (“InGaP2”) emitter layer 324 and a highly doped n-type indium aluminum phosphide (“AlInP2”) window layer 326. The InGaAs base layer 322 of the middle subcell 307 can include, for example, approximately 1.5% In. Other compositions may be used as well. The base layer 322 is formed over the BSF layer 320 after the BSF layer is deposited over the tunneling junction layers 318 of the bottom subcell 304.

In a first embodiment of the present invention, an intrinsic layer constituted by a strain-balanced multi-quantum well structure 323 is formed between base layer 322 and emitter layer 324 of middle subcell B. The strain-balanced quantum well structure 323 includes a sequence of quantum well layers formed from alternating layers of compressively strained InGaAs and tensionally strained gallium arsenide phosphide (“GaAsP”). Strain-balanced quantum well structures are known from the paper of Chao-Gang Lou et al., Current-Enhanced Quantum Well Solar Cells, Chinese Physics Letters, Vol. 23, No. 1 (2006), and M. Mazzer et al., Progress in Quantum Well Solar Cells, Thin Solid Films, Volumes 511-512 (26 Jul. 2006).

In an alternative example, the strain-balanced quantum well structure 323, comprising compressively strained InGaAs and tensionally strained gallium arsenide, may be provided as either the base layer 322 or the emitter layer 324.

In addition to a strain-balanced structure, metamorphic structures may be used as well.

The BSF layer 320 is provided to reduce the recombination loss in the middle subcell 307. The BSF layer 320 drives minority carriers from a highly doped region near the back surface to minimize the effect of recombination loss. Thus, the BSF layer 320 reduces recombination loss at the backside of the solar cell and thereby reduces recombination at the base layer/BSF layer interface. The window layer 326 is deposited on the emitter layer 324 of the middle subcell B after the emitter layer is deposited on the strain-balanced quantum well structure 323. The window layer 326 in the middle subcell B also helps reduce the recombination loss and improves passivation of the cell surface of the underlying junctions. Before depositing the layers of the top cell C, heavily doped n-type InAlP₂ and p-type InGaP₂ tunneling junction layers 327, 328 may be deposited over the middle subcell B.

In the illustrated example, the top subcell 309 includes a highly doped p-type indium gallium aluminum phosphide (“InGaAlP”) BSF layer 330, a p-type InGaP2 base layer 332, a highly doped n-type InGaP2 emitter layer 334 and a highly doped n-type InAIP2 window layer 336. The base layer 332 of the top subcell 309 is deposited over the BSF layer 330 after the BSF layer 330 is formed over the tunneling junction layers 328 of the middle subcell 307. The window layer 336 is deposited over the emitter layer 334 of the top subcell after the emitter layer 334 is formed over the base layer 332. A cap layer 338 may be deposited and patterned into separate contact regions over the window layer 336 of the top subcell 308. The cap layer 338 serves as an electrical contact from the top subcell 309 to metal grid layer 340. The doped cap layer 338 can be a semiconductor layer such as, for example, a GaAs or InGaAs layer. An anti-reflection coating 342 can also be provided on the surface of window layer 336 in between the contact regions of cap layer 338.

In the illustrated example, the strain-balanced quantum well structure 323 is formed in the depletion region of the middle subcell 307 and has a total thickness of about 3 microns (mm). Different thicknesses may be used as well. Alternatively, the middle subcell 307 can incorporate the strain-balanced quantum well structure 323 as either the base layer 322 or the emitter layer 324 without an intervening layer between the base layer 322 and emitter layer 324. A strain-balanced quantum well structure can include one or more quantum wells. As shown in the example of FIG. 3, the quantum wells may be formed from alternating layers of compressively strained InGaAs and tensionally strained GaAsP. An individual quantum well within the structure includes a well layer of InGaAs provided between two barrier layers of GaAsP, each having a wider energy band gap than InGaAs. The InGaAs layer is compressively strained due to its larger lattice constant with respect to the lattice constant of the substrate 312. The GaAsP layer is tensionally strained due to its smaller lattice constant with respect to the substrate 312. The “strain-balanced” condition occurs when the average strain of the quantum well structure is approximately equal to zero. Strain-balancing ensures that there is almost no stress in the quantum well structure when the multijunction solar cell layers are grown epitaxially. The absence of stress between layers can help prevent the formation of dislocations in the crystal structure, which would otherwise negatively affect device performance. For example, the compressively strained InGaAs well layers of the quantum well structure 323 may be strain-balanced by the tensile strained GaAsP barrier layers.

The quantum well structure 323 may also be lattice matched to the substrate 312. In other words, the quantum well structure may possess an average lattice constant that is approximately equal to a lattice constant of the substrate 312. Lattice matching the quantum well structure 323 to the substrate 312 may further reduce the formation of dislocations and improve device performance. Alternatively, the average lattice constant of the quantum well structure 323 may be designed so that it maintains the lattice constant of the parent material in the middle subcell 307. For example, the quantum well structure 323 may be fabricated to have an average lattice constant that maintains the lattice constant of the AlGaAs BSF layer 320. In this way, dislocations are not introduced relative to the middle cell 307. However, the overall device 303 may remain lattice mismatched if the lattice constant of the middle cell is not matched to the substrate 312. The thickness and composition of each individual InGaAs or GaAsP layer within the quantum well structure 323 may be adjusted to achieve strain-balance and minimize the formation of crystal dislocations. For example, the InGaAs and GaAsP layers may be formed having respective thicknesses about 100-300 angstroms (D). Between 100 and 300 total InGaAs/GaAsP quantum wells may be formed in the strain-balanced quantum well structure 323. More or fewer quantum wells may be used as well. Additionally, the concentration of indium in the InGaAs layers may vary between 10-30%.

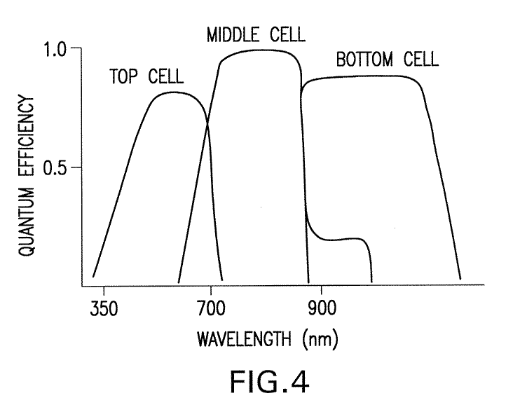

Furthermore, the quantum well structure 323 can extend the range of wavelengths absorbed by the middle subcell 307. An example of approximate quantum efficiency curves for the multijunction solar cell of FIG. 3 is illustrated in FIG. 4. As shown in the example of FIG. 4, the absorption spectrum for the bottom subcell 305 extends between 890-1600 nm; the absorption spectrum of the middle subcell 307 extends between 660-1000 nm, overlapping the absorption spectrum of the bottom subcell; and the absorption spectrum of the top subcell 309 extends between 300-660 nm. Incident photons having wavelengths located within the overlapping portion of the middle and bottom subcell absorption spectrums may be absorbed by the middle subcell 307 prior to reaching the bottom subcell 305. As a result, the photocurrent produced by middle subcell 307 may increase by taking some of the current that would otherwise be excess current in the bottom subcell 304. In other words, the photo-generated current density produced by the middle subcell 307 may increase. Depending on the total number of layers and thickness of each layer within the quantum well structure 323, the photo-generated current density of the middle subcell 307 may be increased to match the photo-generated current density of the bottom subcell 305.

The overall current produced by the multijunction cell solar cell then may be raised by increasing the current produced by top subcell 309. Additional current can be produced by top subcell 309 by increasing the thickness of the p-type InGaP2 base layer 332 in that cell. The increase in thickness allows additional photons to be absorbed, which results in additional current generation. Preferably, for space or ANQ applications, the increase in thickness of the top subcell 309 maintains the approximately 4-5% difference in current generation between the top subcell 309 and middle subcell 307. For AM1 or terrestrial applications, the current generation of the top cell and the middle cell may choose to be mated.

As a result, both the introduction of strain-balanced quantum wells in the middle subcell 307 and the increase in thickness of top subcell 309 provide an increase in overall multijunction solar cell current generation and enable an improvement in overall photon conversion efficiency. Furthermore, the increase in current may be achieved without significantly reducing the voltage across the multijunction solar cell.

In the illustrated implementation, particular III-V semiconductor compounds are used in the various layers of the solar cell structure. However, the multijunction solar cell structure can be formed by other combinations of group III to V elements listed in the periodic table, wherein the group III includes boron (B), aluminum (Al), gallium (Ga), indium (In), and thallium (Ti), the group IV includes carbon (C), silicon (Si), Ge, and tin (Sn), and the group V includes nitrogen (N), phosphorus (P), arsenic (As), antimony (Sb), and bismuth (Bi).

Although the foregoing discussion mentions particular examples of materials and thicknesses for various layers, other implementations may use different materials and thicknesses. Also, additional layers may be added or some layers deleted in the multijunction solar cell structure 303 without departing from the scope of the present invention. In some cases, an integrated device such as a bypass diode may be formed over the layers of the multijunction solar cell structure 303.

Various modifications may be made without departing from the spirit and scope of the invention. Accordingly, other implementations are within the scope of the claims.

1. A multijunction photovoltaic cell, comprising:
a top subcell;
a second subcell disposed immediately adjacent to said top subcell, for producing a first photo-generated current; and including a sequence of first and second different semiconductor layers with different lattice constant; and
a lower subcell disposed immediately adjacent to said second subcell, for producing a second photo-generated current substantially equal in amount to the first photo-generated current.

2. A multijunction photovoltaic cell as defined in claim 1, wherein the sequence of first and second different semiconductor layers forms the base layer of the second subcell.

3. A multijunction photovoltaic cell as defined in claim 1, wherein the sequence of first and second different semiconductor layers comprises compressively strained and tensionally strained layers, respectively.

4. A multifunction photovoltaic cell as defined in claim 1, wherein an average strain of the sequence of first and second different semiconductor layers is approximately equal to zero.

5. A multijunction photovoltaic cell as defined in claim 1, wherein the first and second semiconductor layers are III-V semiconductor compounds, and the lower subcell is composed of germanium.

6. A multijunction photovoltaic cell as defined in claim 1, wherein each of the first and second semiconductor layers is approximately 100 nm to 300 angstroms thick.

7. A multijunction photovoltaic cell as defined in claim 1, wherein the first semiconductor layer comprises InGaAs and the second semiconductor layer comprises GaAsP.

8. A multijunction photovoltaic cell as defined in claim 7, wherein a percentage of indium in each InGaAs layer is in the range of 10 to 30%.

9. A multifunction photovoltaic cell as defined in claim 1, wherein the top subcell comprises InGaP and has a thickness so that it generates approximately 4-5% less current than said first current.

10. A multijunction solar cell comprising:
a semiconductor substrate; and
a sequence of semiconductor layers disposed over the substrate and adapted to form a stack of subcells with the substrate, wherein a middle subcell of the stack comprises a sequence of alternating first and second different semiconductor layers, and wherein an average lattice constant of the sequence of alternating first and second semiconductor layers is approximately equal to a lattice constant of the substrate.

11. The multijunction solar cell of claim 10, wherein the sequence of first and second semiconductor layers form a base layer of the middle subcell.

12. The multijunction solar cell of claim 10, wherein the sequence of first and second semiconductor layers is disposed between a base layer and emitter layer of the middle subcell.

13. The multijunction solar cell of claim 10, wherein the total thickness of the sequence of first and second semiconductor layers is approximately 3 microns.

14. The multifunction solar cell of claim 10, wherein the thickness of each of the first and second semiconductor layers is in the range of 100 to 300 angstroms.

15. A multijunction solar cell comprising:
a semiconductor structure including a sequence of semiconductor layers disposed and adapted to form a vertical stack of solar subcells; and
a plurality of semiconductor layers disposed in a middle subcell in the stack, wherein each alternating layer comprises a first compressively strained semiconductor layer and a second tensionally strained semiconductor layer.

16. The multijunction solar cell of claim 15, wherein the thickness of the layers of the middle solar cell is selected so that photo-generated current of the middle subcell is substantially equal to the photo-generated current density of the lower subcell adjacent to the middle subcell.

17. The multijunction solar cell of claim 15, wherein the semiconductor structure is grown on a semiconductor substrate and the average lattice constant of the plurality of semiconductor layers in the middle cell is approximately equal to the lattice constant of the semiconductor substrate.

18. The multijunction solar cell of claim 15, wherein the average of the strains of the plurality of strained layers is approximately zero.

19. The multifunction solar cell of claim 15, wherein each strained semiconductor layer comprises a III-V semiconductor compound and forms a quantum well.

20. The multifunction solar cell of claim 15, wherein the plurality of semiconductor layers have a total thickness of approximately 3 microns.
